(19) United States
(12) Patent Application Publication
(10) Pub. No.: US 2025/0389927 A1
(43) Pub. Date: Dec. 25, 2025

(54) OPTICAL MODULES FOR THE ULTRAVIOLET WAVELENGTH RANGE

(71) Applicant: Carl Zeiss SMT GmbH, Oberkochen (DE)

(72) Inventors: Stephan SIX, Oberkochen (DE); Toralf GRUNER, Oberkochen (DE); Stig BIELING, Oberkochen (DE); Markus SCHWAB, Oberkochen (DE); Talea WENZEL, Oberkochen (DE); Michael WAGENPFEIL, Oberkochen (DE); Ulrich LOERING, Oberkochen (DE); Vitaliy SHKLOVER, Oberkochen (DE)

(21) Appl. No.: 19/311,472

(22) Filed: Aug. 27, 2025

Related U.S. Application Data
(63) Continuation of application No. PCT/EP2024/054588, filed on Feb. 22, 2024.

(30) Foreign Application Priority Data
Feb. 27, 2023 (DE) 10 2023 201 742.3

(51) Int. Cl. G02B 7/02; G02B 1/11; G02B 1/14

(52) U.S. Cl. CPC G02B 7/025; G02B 1/11; G02B 1/14

(57) ABSTRACT

This disclosure relates to an optical module comprising an optical element for a working wavelength range in the ultraviolet wavelength range and a holder, wherein the optical element is bonded to the holder by irradiation of an adhesive curable at a curing wavelength range in the ultraviolet wavelength range, and wherein the module has a protective adhesive coating, wherein the protective adhesive coating is multi-layered and is highly reflective and slightly absorbent in the working wavelength range. Furthermore, an optical module is proposed in which the adhesive protective coating that absorbs at the working wavelength has an anti-reflective coating, as well as an optical module that has a diffractive structure in the region of the adhesive.

### CROSS REFERENCE TO RELATED APPLICATIONS

This is a Continuation of International Application PCT/EP2024/054588, which has an international filing date of Feb. 22, 2024, and which claims the priority of German Patent Application 10 2023 201 742.3, filed Feb. 27, 2023. The disclosures of both applications are incorporated in their respective entireties into the present Continuation by reference.

### FIELD

The present disclosure relates to optical modules, comprising an optical element for an operating wavelength in the ultraviolet wavelength range and a holder, wherein the optical element is adhesively bonded to the holder by adhesive that is curable by irradiation at a curing wavelength in the ultraviolet wavelength range, and wherein the module has an adhesive protection coating. The disclosed techniques further relate to an optical system and to a device comprising one of the optical modules mentioned.

### BACKGROUND

DE 10 2011 080 639 A1 discloses an assembly for a DUV microlithography projection exposure apparatus, in particular, which consists of a holder and a component which is adhesively bonded by an adhesive and which transmits radiation in the ultraviolet spectral range. The adhesive is curable by UV light. In the region of the adhesive, a layer is present which transmits UV light from the spectral range suitable for curing the adhesive and absorbs UV light from a used spectral range. What is specified as particularly suitable is an absorbent layer composed of tantalum pentoxide, which achieves a high transmission at a curing wavelength of 365 nm and a very low transmission at a used wavelength of 248 nm or less and, at the same time, a high absorption and a low reflection throughout in both spectral ranges.

### SUMMARY

It is an object of techniques disclosed herein to develop the known assembly further.

This object may be achieved by an optical module, comprising an optical element for an operating wavelength in the ultraviolet wavelength range and a holder, wherein the optical clement is adhesively bonded to the holder by adhesive that is curable via irradiation at a curing wavelength in the ultraviolet wavelength range, and wherein the module has an adhesive protection coating, wherein the adhesive protection coating is of a multilayered design and is highly reflective and slightly absorbent at the operating wavelength.

It has been found that providing reflective multilayered adhesive protection coatings makes it possible as it were to tailor suitable adhesive protection coatings for any desired combinations of operating wavelengths and curing wavelengths, which additionally make it possible to avoid unwanted changes in the optical properties of the optical element on account of heating by absorbed radiation, such as for instance an inhomogeneous change in the refractive index in the lens as a consequence. Such changes in the refractive index may lead to undesired wavefront deformation that influences the imaging properties of the lens. The choice of the layer materials, layer thicknesses and number of layers allows flexible influencing of the reflection, transmission and absorption for specific wavelengths or wavelength ranges. Overall, a wavelength is referenced in the case of a wavelength range with a width of ±1%. In the case of a wider wavelength range, the central wavelength can alternatively be taken into consideration. In particular, not only is it possible to set the reflection at the operating wavelength to be as high as possible and the absorption at the operating wavelength, in particular, to be as low as possible, but it is also possible to set the transmission at the curing wavelength, in particular, to be high enough for the adhesive curing process. Advantageously, the absorption at both the operating and the curing wavelengths should be low enough that undesired heating of the optical element that would entail a change in the optical properties beyond the manufacturing tolerances does not occur. A residual absorption present in this context can be used to further reduce the radiation loading of the adhesive at the operating wavelength over and above the reflection at the adhesive protection layer. Highly reflective should be understood here to mean a reflection of 70% or more, and slightly absorbent an absorption of 30% or less.

Advantageously, the adhesive protection coating has at least three layers in order that in particular the reflection at the operating wavelength can be influenced and increased purposefully by way of a choice of the layer materials and layer thicknesses.

In specific embodiments, the adhesive protection coating has layers composed of a material having a higher refractive index at the operating wavelength and composed of a material having a lower refractive index at the operating wavelength, wherein the layers composed of the material having the higher refractive index and the layers composed of the material having the lower refractive index are arranged alternately in each case. Reflection can take place at each layer boundary. A corresponding choice of the layer thicknesses as a function of the incident wavelength makes it possible to increase the overall total reflection at the adhesive protection coating and to reduce the absorption. In this case, it is particularly advantageous to choose the layer thicknesses to be of the order of one quarter of the incident wavelength. In order to attain the highest possible reflection at a wavelength, optical thicknesses of the order of half the wavelength are preferably employed for a layer pair composed of a layer composed of a material having a higher refractive index and composed of a material having a lower refractive index. The refractive index of the respective layer materials influences the optical thickness.

Advantageously, the adhesive protection coating has at least two layers of the material having a higher refractive index at the operating wavelength and at least one layer of the material having a lower refractive index at the operating wavelength, in order to be able to obtain an increase in the reflection and at the same time a reduction of the absorption at the operating wavelength in particular. In this case, moreover, the transmission at the curing wavelength can be kept high enough for curing the adhesive.

For these purposes, the adhesive protection coating preferably has between three and sixteen layers of the material having a higher refractive index at the operating wavelength and between three and sixteen layers of the material having a lower refractive index at the operating wavelength. These numbers of layers allow an efficient setting of the reflection without at the same time incurring excessively high coating outlay.

Advantageously, the adhesive protection coating has a layer composed of the material having a higher refractive index at the operating wavelength as an outermost layer on the adhesive side. It is likewise advantageous if the adhesive protection coating has a layer composed of the material having a higher refractive index at the operating wavelength as an outermost layer on its side facing away from the adhesive. Both measures, separately or else in combination, can contribute to increasing the reflection at the operating wavelength. In the latter case, preferably, the thickness of the outermost layer facing away from the adhesive can be a different thickness than that of the other layers composed of the material having a higher refractive index at the operating wavelength. In the case of a multilayered adhesive protection coating that is optimized for a particularly high reflection in the range of the operating wavelength, the transmission in the range of the curing wavelength can be increased by this measure.

Preferably, all the layers of a material having a higher or lower refractive index at the operating wavelength have the same thickness. The resulting, as it were periodic, construction of the adhesive protection coating makes it possible to greatly increase the reflection for narrower operating wavelength ranges, in particular, with widths in the nanometer or subnanometer range or to greatly reduce the absorption. Therefore, such modules are particularly well suited to use with, for instance, lasers as radiation source.

In one embodiment, the operating wavelength is not equal to the curing wavelength, in which case the adhesive protection coating has a reflection of greater than 70%, preferably greater than 80%, particularly preferably greater than 90%, at the operating wavelength and a transmission of greater than 90% at the curing wavelength. Consequently, after unobstructed curing, impairments of the optical properties due to unwanted heating of the optical element can be effectively avoided. According to specific embodiments, the optical module is designed for an operating wavelength of around 193 nm or 248 nm and a curing wavelength of around 365 nm.

In a further embodiment, the operating wavelength is equal to the curing wavelength, in which case the adhesive protection coating has a reflection of greater than 70%, preferably greater than 80%, particularly preferably greater than 90%, at the operating wavelength and a transmission of greater than 2%, preferably 6%, at the curing wavelength. In this way, any impairments of the optical properties due to unwanted heating of the optical element can be effectively avoided, without preventing curing of the adhesive. According to specific embodiments, the optical module is designed for an operating and a curing wavelength of around 365 nm.

The adhesive protection coating may be comprised of at least one material, and certain embodiments two materials, from the group formed from silicon dioxide, aluminum oxide, hafnium dioxide, tantalum pentoxide, titanium dioxide, zinc sulfide, aluminum fluoride, cryolite, chiolite and magnesium fluoride. According to specific embodiments, the adhesive protection coating has, as the material having a higher refractive index at the operating wavelength, at least one material from the group formed from hafnium dioxide, aluminum oxide, tantalum pentoxide, titanium dioxide and zinc sulfide and has, as the material having a lower refractive index at the operating wavelength, at least one material from the group formed from silicon dioxide, aluminum fluoride, magnesium fluoride, chiolite and cryolite. Especially for the ultraviolet wavelength range of between 150 nm and 400 nm, these materials allow for the production of multilayered adhesive protection coatings with a large difference in refractive index at the operating wavelength, which can lead to correspondingly high reflection. What is particularly advantageous is the combination of lower refractive index silicon dioxide with higher refractive index aluminum oxide for operating wavelengths of, in particular, around 193 nm and 248 nm or with higher refractive index hafnium dioxide for, in particular, an operating wavelength of around 248 nm and with higher refractive index tantalum pentoxide for an operating wavelength of around 365 nm.

In a further aspect, is the objects of the techniques of this disclosure may be achieved by an optical module, comprising an optical clement for an operating wavelength in the ultraviolet wavelength range and a holder, wherein the optical element is adhesively bonded to the holder by an adhesive, and wherein the module has an adhesive protection coating that is absorbent at the operating wavelength, and the adhesive protection coating has an anti-reflection coating.

This optical module has the advantage that the adhesive protection coating with an anti-reflection coating not only protects the adhesive against radiation damage but also suppresses the residual reflection that could lead to disturbance rays. The module is particularly well suited in conjunction with optical elements which, when heated, do not significantly affect the wavefront of an imaging when they are installed in the beam path of an optical system.

In one specific embodiment, the anti-reflection coating has layers composed of a material having a higher refractive index at the operating wavelength and layers composed of a material having a lower refractive index in the operating wavelength range, wherein the layers composed of the material having the higher refractive index and the layers composed of the material having the lower refractive index are arranged alternately in each case. The choice of the layer materials, layer thicknesses and number of layers allows flexible influencing of the reflection, transmission and absorption for specific wavelengths or wavelength ranges. Overall, a wavelength is referenced in the case of a wavelength range with a width of ±1%. In the case of a wider wavelength range, the central wavelength can alternatively be taken into consideration. In order to attain the lowest possible reflection at a wavelength, optical thicknesses of the order of one quarter of the wavelength, but also significantly more or less than that, are employed for a layer pair composed of a layer composed of a material having a higher refractive index and composed of a material having a lower refractive index. The refractive index of the respective layer materials influences the optical thickness. Preferably, the anti-reflection coating of the adhesive protection coating, like the multilayered adhesive protection coating described above, has at least one material, preferably two materials, from the group formed from silicon dioxide, aluminum oxide, hafnium dioxide, tantalum pentoxide, titanium dioxide, zinc sulfide, aluminum fluoride, cryolite, chiolite and magnesium fluoride. Particularly, the adhesive protection coating may have, as the material having a higher refractive index at the operating wavelength, one material from the group formed from hafnium dioxide, aluminum oxide, tantalum pentoxide, titanium dioxide and zinc sulfide and has, and as a material having a lower refractive index at the operating wavelength, one material from the group formed from silicon dioxide, aluminum fluoride, magnesium fluoride, chiolite and cryolite.

In a further embodiment, the anti-reflection coating is embodied as a coating with a refractive index gradient. As a result, the anti-reflection effect takes effect for a wider wavelength range. Particularly advantageously, the refractive index changes from the refractive index of the material of the optical element through to the refractive index of the material of the adhesive protection coating. A particularly good anti-reflection effect can be obtained by as continuous a change in the refractive index as possible.

In a further aspect, the object is achieved by an optical module, comprising an optical element for an operating wavelength in the ultraviolet wavelength range and a holder, wherein the optical element is adhesively bonded to the holder by an adhesive, and wherein the module has a diffractive structure in the region of the adhesive.

What can be achieved by providing a diffractive structure is that radiation at the operating wavelength does not reach the adhesive and damage it in the process. Further this radiation is not reflected at the edge of the optical element with the contrast of the imaging being reduced by the optical element, nor is this radiation absorbed with a resulting contribution to heating of the optical element that would have a disturbing influence on the wavefront and thus on the imaging, especially in the case of inhomogeneous or only local heating. For this purpose, the diffractive structure is preferably structured in such a way that the used radiation incident there is diffracted from the beam path. Particularly preferably, diffractive structures embodied as periodic diffraction gratings are provided. The provision of a diffractive structure can also be combined with a highly reflective or, in particular, an anti-reflective adhesive protection coating in order to remove disturbance radiation at different wavelengths or at different angles of incidence from the beam path.

Preferably, the diffractive structure is at an angle of inclination with respect to the normal to the surface of the optical element, especially if the diffractive structure is embodied as a periodic diffraction grating. This has the great advantage that, in contrast to diffractive structures without an angle of inclination, not only are the first and second orders of diffraction diffracted from the beam path, but so too is the zero order, which is at the same time the order of highest intensity. In the case of a diffractive structure with varying heights and angles of inclination, it is also possible to achieve an anti-reflection effect for a larger wavelength or angle-of-incidence range.

Advantageously, the optical module has a radiation absorber. The radiation absorber can absorb the diffracted radiation and thus efficiently remove it from the beam path.

According to embodiments of all the modules mentioned above, the optical element may be designed as a lens. The optical modules are thus suitable for, in particular, use in UV lithography devices and inspection systems for examining masks for exposure via lithography or else wafers before or after exposure.

Moreover, the objects of this disclosure may be achieved by an optical system comprising one of the optical modules as described above. Furthermore, the objects may be achieved by a device comprising one of the optical modules as described above or comprising an optical system as just mentioned, wherein the device is designed as a UV lithography device or an inspection device.

### BRIEF DESCRIPTION OF THE DRAWINGS

The techniques of the present disclosure will be explained in greater detail with reference to an exemplary embodiment. In this respect:

FIG. 1 shows a basic schematic diagram of a UV lithography device;

FIG. 2 shows a basic schematic diagram of an inspection system;

FIG. 3 shows a basic schematic diagram of an optical module;

FIG. 4 shows a basic schematic diagram of an adhesive protection coating of an optical module;

FIG. 5 shows the reflection as a function of the wavelength for a first and a second exemplary embodiment of an adhesive protection coating;

FIG. 6 shows the transmission as a function of the wavelength for the first and second exemplary embodiments of an adhesive protection coating;

FIG. 7 shows the reflection as a function of the wavelength for a third and a fourth exemplary embodiment of an adhesive protection coating;

FIG. 8 shows the transmission as a function of the wavelength for the third and fourth exemplary embodiments of an adhesive protection coating;

FIG. 9 shows the reflection as a function of the wavelength for a fifth and a sixth exemplary embodiment of an adhesive protection coating;

FIG. 10 shows the transmission as a function of the wavelength for the fifth and sixth exemplary embodiments of an adhesive protection coating;

FIG. 11 shows a basic schematic diagram of a second optical module;

FIG. 12 shows the proportion of the oxygen concentration as a function of the distance from the lens surface for a first embodiment of an adhesive protection coating with an anti-reflection coating;

FIG. 13 shows the reflection as a function of the wavelength for the first embodiment of an adhesive protection coating with an anti-reflection coating;

FIG. 14 shows the reflection as a function of the angle of incidence for the first embodiment of an adhesive protection coating with an anti-reflection coating;

FIG. 15 shows the reflection as a function of the wavelength for a second embodiment of an adhesive protection coating with an anti-reflection coating;

FIG. 16 shows the transmission as a function of the wavelength for a second embodiment of an adhesive protection coating with an anti-reflection coating;

FIG. 17 shows a basic schematic diagram of a third optical module; and

FIG. 18 shows a basic schematic diagram of one embodiment of the third optical module.

### DETAILED DESCRIPTION

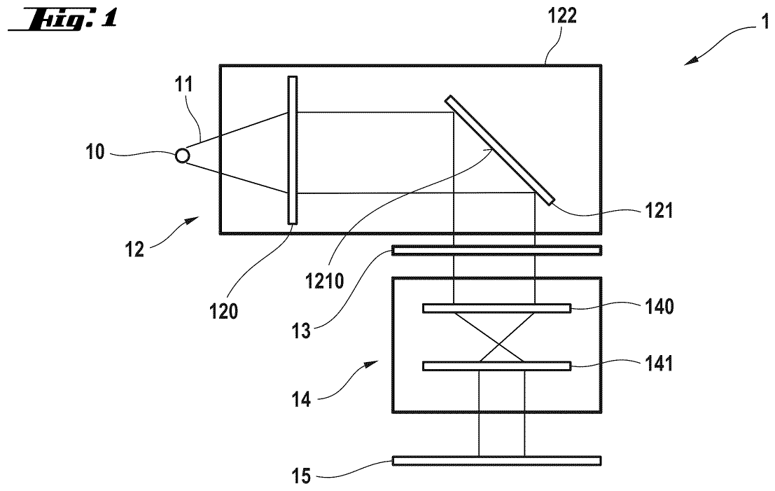

FIG. 1 shows a basic schematic diagram of a device 1 for UV lithography for, in particular, wavelengths in the range of 190 nm to 400 nm. The UV lithography device 1 comprises, as essential components in particular, two optical systems 12, 14, an illumination system 12 and a projection system 14. Carrying out the lithography necessitates a radiation source 10, such as an excimer laser, which emits at, for example, 193 nm or 248 nm and which can be an integral part of the UV lithography device. A mercury lamp may also be used, wherein the emitted i-line around 368 nm can be used as an operating wavelength and/or, in an adhesive bonding process carried out outside the respective optical system, as a curing wavelength. The radiation 11 emitted by the radiation source 10 is conditioned with the aid of the illumination system 12 such that a mask 13, also called a reticle, can be illuminated thereby. In the example illustrated here, the illumination system 12 comprises transmissive and reflective optical elements. The transmissive optical element 120, which focuses the radiation 11, for example, and the reflective optical element 121, which deflects the radiation, for example, are illustrated here in representative fashion. All the optical elements can be part of an optical module as proposed here. In a known manner, in the illumination system 12, a wide variety of transmissive, reflective and other optical elements can be combined with one another in an arbitrary, and even more complex, manner. It should be pointed out that the mask 13 can also be part of an optical module proposed here.

The mask 13 has a structure on its surface, said structure being transferred to an element 15 to be exposed, for example a wafer in the context of the production of semiconductor components, with the aid of the projection system 14. In the present example, the mask 13 is embodied as a transmissive optical element. In further embodiments, it can also be configured as a reflective optical element. The projection system 14 comprises at least one transmissive optical element in the example illustrated here. In the example illustrated here, two transmissive optical elements 140, 141 are illustrated in representative fashion, which serve to, for example, reduce the structures on the mask 13 to the size desired for the exposure of the wafer 15. In the projection system 14, inter alia, one or more reflective optical elements can be provided and a wide variety of optical elements can be combined with one another arbitrarily in a known manner. It should be pointed out that optical systems without transmissive optical elements can also be provided, in particular in the case of optical systems which are optimized for wavelengths of less than 200 nm. All the optical elements of the projection system 14 can also be part of an optical module proposed here.

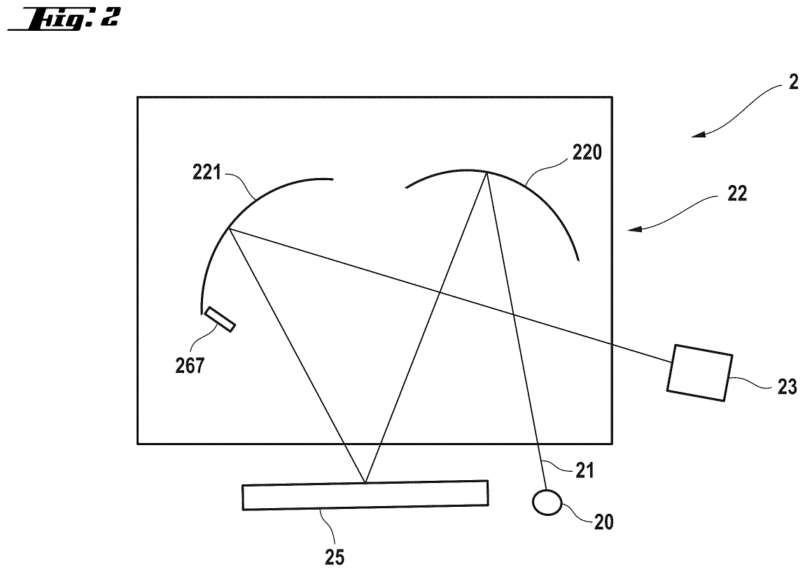

Optical modules comprising an optical element for an operating wavelength in the ultraviolet wavelength range and a holder, wherein the optical element is adhesively bonded to the holder by adhesive that is curable via irradiation in a curing wavelength range in the ultraviolet wavelength range, and wherein the module has an adhesive protection coating, wherein the adhesive protection coating is of multilayered design and is highly reflective and slightly absorbent at the operating wavelength, can also be used in wafer or mask inspection systems. One exemplary embodiment of a wafer inspection system 2 is illustrated schematically in FIG. 2. The explanations are likewise applicable to mask inspection systems.

The wafer inspection system 2 comprises a radiation source 20, the radiation of which is directed onto a wafer 25 by an optical system 22. For this purpose, the radiation is reflected from a concave mirror 220 onto the wafer 25. In the case of a mask inspection system, a mask to be examined could be arranged in the system 2 in place of the wafer 25. The radiation reflected, diffracted and/or refracted by the wafer 25 is directed onto a detector 23 for further evaluation by a concave mirror 221, which is likewise associated with the optical system 22. The radiation source 20 can be, for example, exactly one radiation source or a combination of a plurality of individual radiation sources in order to provide a substantially continuous radiation spectrum. In modifications, one or more narrowband radiation sources may also be used. The inspection system, illustrated by way of example here, is designed for an operating wavelength in the range of between 190 nm and 300 nm, particularly preferably between 190 nm and 200 nm. In addition and/or as an alternative to the two concave mirrors 220, 221, it is also possible to provide lenses in the wafer or mask inspection system. In the case of inspection systems designed for operating wavelengths in the range of 200 nm to 400 nm, in particular 300 nm to 400 nm, all the optical elements can be embodied as lenses.

FIG. 3 illustrates one exemplary embodiment of an optical module 300. In the present example, the optical clement 301 is a concave lens that is transparent to an operating wavelength in the ultraviolet wavelength range. The lens 301 is mounted into a holder 303. For this purpose, the lens is fixedly adhesively bonded to the holder 303 by a UV-curable adhesive 305, which may be outside the region used optically during operation. By way of example, epoxy-based adhesives that can be cured using UV radiation of the i-line of a mercury lamp are used as mounting adhesives. As a result of the irradiation of the lens during operation by, in particular, stray light or multiple reflections, in the long term the adhesive may incur radiation damage and lose adhesion or become deformed, such that the lens 301 is no longer held in the originally adjusted position in the holder 303 and imaging aberrations may occur. Therefore, an adhesive protection coating 307 is provided between lens 301 and adhesive 305. The adhesive protection coating 307 is of multilayered design and is highly reflective and slightly absorbent at the operating wavelength. Similar to dielectric multilayered anti-reflection coatings a are known to be provided on lenses, the adhesive protection coating can be applied by customary coating methods of thin-film technology, such as thermal electron beam evaporation or magnetron sputtering, for example. In order to increase the mechanical strength of the optical module 300, ion-assisted coating methods are preferably chosen. In order to simplify handling, the adhesive protection coating 307 can be applied locally on the lens 301 before it is adhesively bonded together with the holder 303. Afterward, the adhesive can be cured by irradiation 309 (indicated by the dashed arrow) at the curing wavelength, to which the adhesive protection coating 307 is sufficiently transparent. At the operating wavelengths, most of the incident radiation 309 is reflected out of the beam path, such that the absorption at the adhesive bonding joint is low enough to avoid local heating of the lens 301 that might lead to imaging aberrations caused by wavefront aberration, for instance. The absorption that may be present may be low enough to avoid undesired heating and can additionally contribute to the protection of the adhesive 305 against radiation damage.

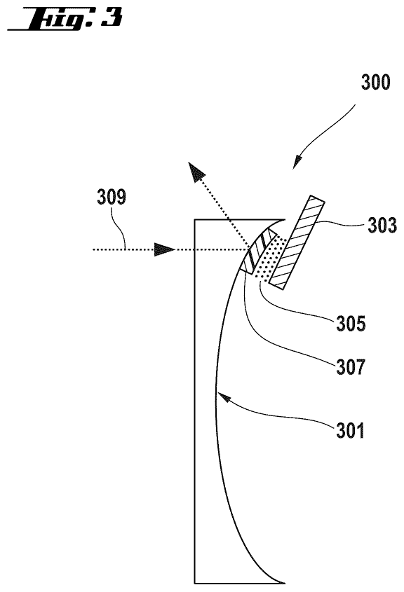

The region of the adhesive protection coating of the optical module is illustrated in greater detail in FIG. 4. The adhesive protection coating 407 is arranged between the optical element 401 and the adhesive 405. The adhesive protection coating 407 is constructed in a multilayered fashion, preferably from at least three layers. The choice of the number of layers, the layer thickness and the layer materials makes it possible, for any desired combinations of operating wavelength and curing wavelength, to establish the reflection, transmission and absorption at the relevant wavelengths such that the reflection is as high as possible and the absorption is as low as possible in order to avoid undesired heating of the optical element 401 and also radiation damage at the adhesive 405, and the transmission at the curing wavelength is nevertheless high enough in order to be able to cure the adhesive 405.

It has proved to be particularly worthwhile if the adhesive protection coating 407 has layers 471 composed of a material having a higher refractive index at the operating wavelengths and layers 473 composed of a material having a lower refractive index at the operating wavelength, wherein the layers 471 composed of the material having the higher refractive index and the layers 473 composed of the material having the lower refractive index are arranged alternately in each case. In this way, it is possible, and particularly efficient, to design an adhesive protection coating 407 which, for in the case of a freely chosen operating wavelength and curing wavelength in the ultraviolet wavelength range, satisfies the requirements with respect to high reflection in conjunction with low absorption and sufficient transmission. Preferably, the adhesive protection coating 407 has at least two layers 471 of the material having a higher refractive index at the operating wavelength and at least one layer 473 of the material having a lower refractive index at the operating wavelength. In specific examples, the adhesive protection coating 407 has between three and sixteen layers 471 of the material having a higher refractive index at the operating wavelength and between three and sixteen layers 473 of the material having a lower refractive index at the operating wavelength.

In the example illustrated in FIG. 4, provision is made of respectively four layers 471 of the material having a higher refractive index at the operating wavelength and three layers 473 of the material having a lower refractive index at the operating wavelength. A layer 471′, 471 composed of the material having a higher refractive index is provided as a respective outermost layer both on the adhesive side and facing away from the adhesive. In the example illustrated here, all the layers 471 of the material having a higher refractive index and all the layers 473 of the material having a lower refractive index each have the same thickness, while the thickness of the outermost layer 471′ on the adhesive side is a different thickness than that of the other layers 471 composed of the material having a higher refractive index. There is thus, in essence, a periodic layer sequence distinguished by particularly high reflection at a wavelength, in particular if there is a unit composed of two adjacently arranged layers 471, 473 composed of material having higher and lower refractive indices at approximately one quarter of said wavelength. If necessary, the periodicity can be broken by the outermost layer on the adhesive side in order to increase the transmission at the curing wavelength somewhat in order to allow faster curing. As an alternative thereto, the bottommost layer 471 comprising material having a higher refractive index on the optical element 401 can also have a different thickness than one quarter of the operating wavelength in order thereby to obtain the highest possible transmission at the curing wavelength in a targeted manner, while the reflection at the operating wavelength is still kept at a high value. Silicon dioxide, aluminum oxide, hafnium oxide, tantalum pentoxide, titanium dioxide, zinc sulfide, aluminum fluoride, cryolite, chiolite and magnesium fluoride in combination with another or a plurality of these materials or one or more further materials have proved to be worthwhile as materials for the adhesive protection coating 407. The combinations of hafnium oxide, aluminum oxide, tantalum pentoxide, titanium dioxide or zinc sulfide as the material having a higher refractive index with silicon dioxide, aluminum fluoride, magnesium fluoride, chiolite and cryolite as the material having a lower refractive index have proved to be particularly worthwhile.

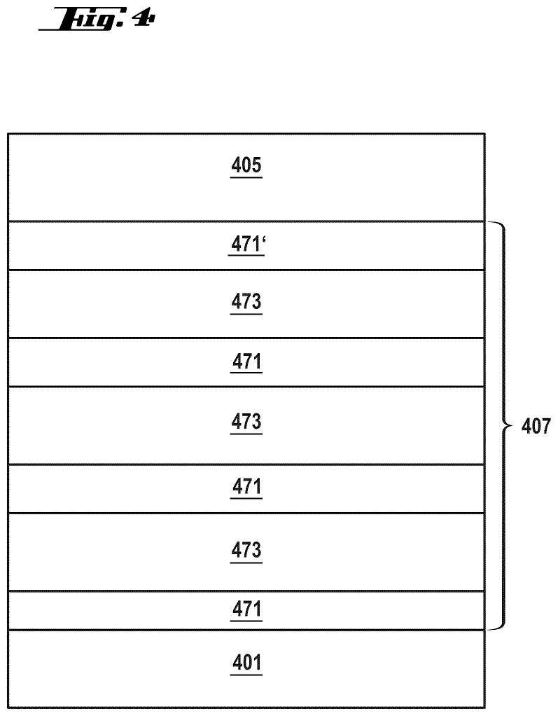

The reflection and transmission curves for various embodiments of adhesive protection coatings are illustrated in the following figures. In FIG. 5 the reflection and in FIG. 6 the transmission are plotted as a function of the wavelength of two adhesive protection coatings A and B, which are both optimized for an operating wavelength λ₁ of 193 nm and a curing wavelength λ₂ of 365 nm. The adhesive protection coating A has fourteen layers with a thickness of 27 nm composed of aluminum oxide as the material having a higher refractive index and thirteen layers with a thickness of 31 nm of silicon dioxide as the material having a lower refractive index, which are arranged alternately. The reflection and transmission for the adhesive protection coating A are respectively plotted as a dashed line. The adhesive protection coating B has only ten layers with a thickness of 27 nm composed of aluminum oxide as the material having a higher refractive index and nine layers with a thickness of 31 nm of silicon dioxide as the material having a lower refractive index, which are arranged alternately. The reflection and transmission for the adhesive protection coating B are respectively plotted as a solid line. The adhesive protection coating B has a reflection of almost 80% and a transmission of almost 20% at the operating wavelength λ₁ and a reflection of practically 0% and a transmission of practically 100% at the curing wavelength λ₂, such that virtually no absorption of the respective radiation takes place both in the range of the operating wavelength λ₁ and in the range of the curing wavelength λ₂, such that no undesired heating of the respective optical element takes place, but the curing of the adhesive can take place as though no adhesion protection coating were present, and the cured adhesive is nevertheless protected against radiation damage. Increasing the number of layers in the adhesive protection coating A even results in a reflection of more than 90% and a transmission of less than 10% at the operating wavelength λ₁, whereby the adhesive is even better protected against radiation damage and has a correspondingly longer lifetime. The residual absorption in the adhesive protection coating of less than 1% here leads only to lens heating that is so low that the wavefront and imaging properties are not changed outside the necessary requirements. Rather, it serves here to be used to additionally protect the adhesive against radiation damage by virtue of the absorption of the residual radiation energy.

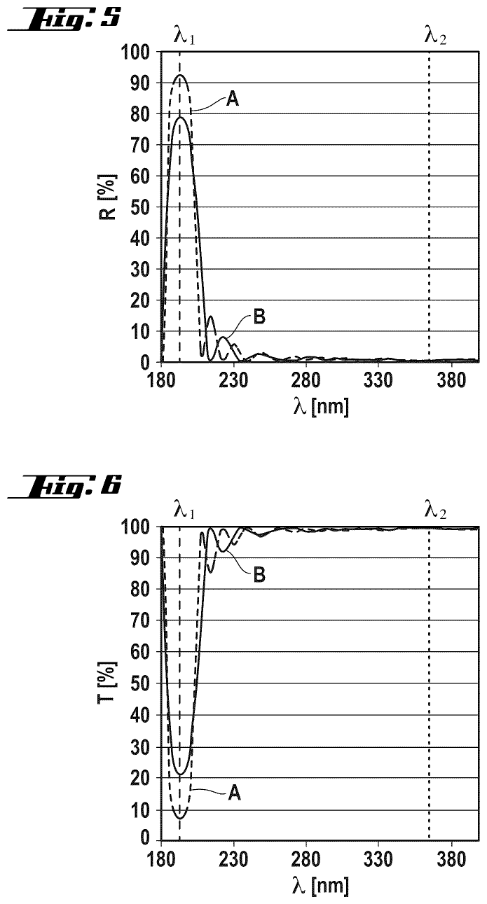

In FIG. 7 the reflection and in FIG. 8 the transmission are plotted as a function of the wavelength of two adhesive protection coatings C and D, which are both optimized for an operating wavelength λ₁ of 248 nm and a curing wavelength λ₂ of 365 nm. The adhesive protection coating C has seven layers with a thickness of 30 nm composed of hafnium oxide as the material having a higher refractive index and seven layers with a thickness of 40 nm of silicon dioxide as the material having a lower refractive index, which are arranged alternately. As a topmost layer, finally, a further layer composed of hafnium dioxide with a thickness of 15 nm also follows on the adhesive side. The reflection and transmission for the adhesive protection coating C are respectively plotted as a dashed line. The adhesive protection coating D has only five layers with a thickness of 30 nm composed of hafnium oxide as the material having a higher refractive index and five layers with a thickness of 40 nm of silicon dioxide as the material having a lower refractive index, which are arranged alternately. The reflection and transmission for the adhesive protection coating D are respectively plotted as a solid line. The adhesive protection coating D has a reflection of almost 95% and a transmission of somewhat above 5% at the operating wavelength λ₁ and a reflection of practically 0% and a transmission of practically 100% at the curing wavelength λ₂, such that virtually no absorption of the respective radiation takes place both in the range of the operating wavelength λ₂ and in the range of the curing wavelength λ₂, such that no undesired heating of the respective optical element takes place, but the curing of the adhesive can take place as though no adhesion protection coating were present, and the cured adhesive is nevertheless protected against radiation damage. Increasing the number of layers in the adhesive protection coating C even results in a reflection of almost 100% and a transmission of almost 0% at the operating wavelength λ₁, whereby the adhesive is even better protected against radiation damage and has a correspondingly longer lifetime. At the curing wavelength λ₂, the reflection is approximately 2% and the transmission is approximately 98%, which however still allows totally unobstructed curing of the adhesive. The residual absorption in the adhesive protection coating of less than 1% here leads only to lens heating that is so low that the wavefront and imaging properties are not changed outside the necessary requirements. Rather, it serves here to be used to additionally protect the adhesive against radiation damage by virtue of the absorption of the residual radiation energy.

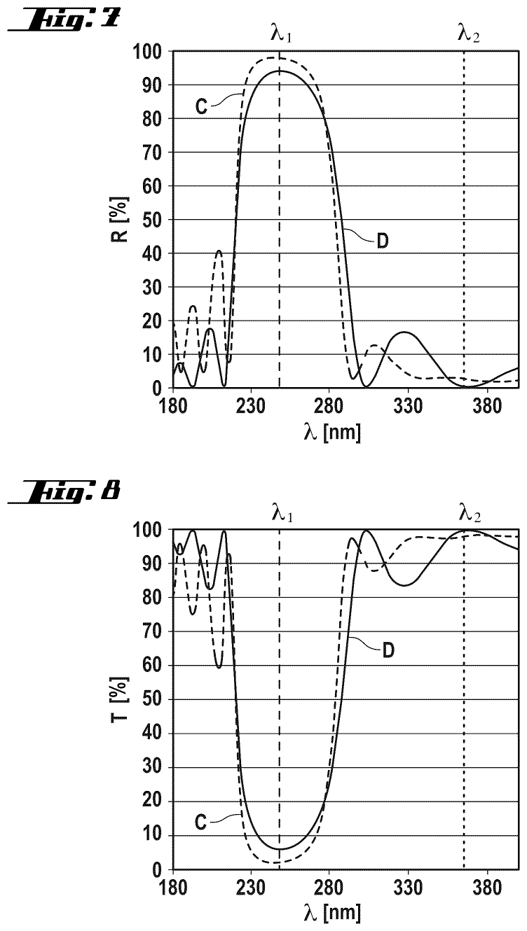

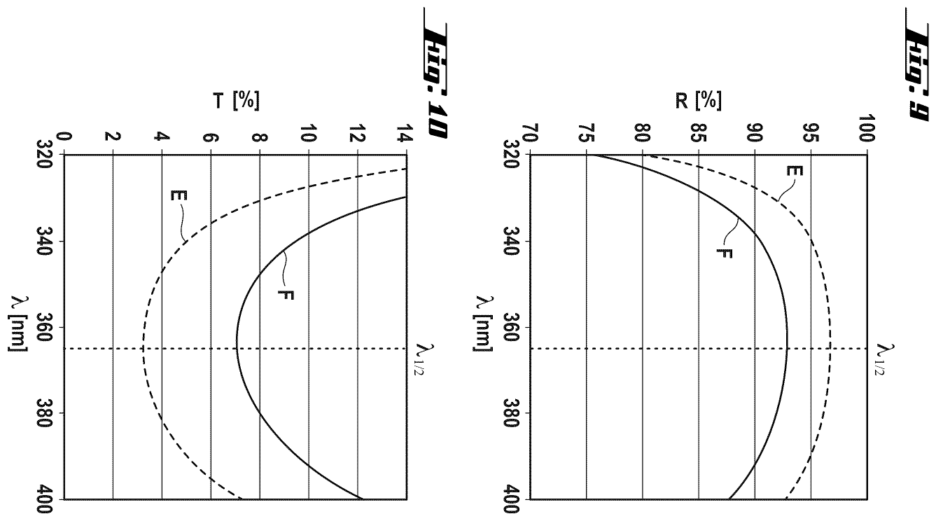

In FIG. 9 the reflection and in FIG. 10 the transmission are plotted as a function of the wavelength of two adhesive protection coatings E and F, which are both optimized for an operating wavelength and respectively a curing wavelength Min of 365 nm. The adhesive protection coating E has seven layers with a thickness of 42 nm composed of tantalum pentoxide as the material having a higher refractive index and six layers with a thickness of 60 nm of silicon dioxide as the material having a lower refractive index, which are arranged alternately. The reflection and transmission for the adhesive protection coating E are respectively plotted as a dashed line. The adhesive protection coating F has only five layers with a thickness of 42 nm composed of tantalum pentoxide as the material having a higher refractive index and four layers with a thickness of 60 nm of silicon dioxide as the material having a lower refractive index, which are arranged alternately. The reflection and transmission for the adhesive protection coating F are respectively plotted as a solid line. The adhesive protection coating E has a reflection of approximately 97% and a transmission of somewhat above 3% at the operating and curing wavelength λ_{1/2}, such that virtually no absorption of the respective radiation takes place in this wavelength range, such that no undesired heating of the respective optical element takes place. The rather low transmission can be compensated for by a longer irradiation duration for the curing of the adhesive. Reducing the number of layers in the adhesive protection coating F still results in a reflection of approximately 93% and a transmission of approximately 7% at the operating and curing wavelength λ_{1/2}, whereby the adhesive cures to a first approximation twice as fast as in the case of the adhesive protection coating E.

In order to estimate the transmission required for curing the adhesive in, for example, the case of the i-line of 365 nm of a mercury lamp as the curing wavelength, it is possible to have recourse to the required irradiation dose D in J/cm², the maximum permissible irradiation duration t in s and the power density P in W/cm² of the mercury lamp used for curing on the optical element in each case at the curing wavelength. The required transmission at the curing wavelength in percent is then calculated as

$$T = 100 \% * D / ( P * t ) .$$

The minimum permissible reflection at the operating wavelength can be correspondingly estimated from the guaranteed lifetime t_{LT} in s, the maximum radiation dose D_{degradation} in J/cm² under which the function of the adhesive is still maintained, and the power density-occurring at the adhesive bonding joint—of stray light and residual reflections P_{stray} in W/cm² and is then calculated as

$$R = 100 \% * ( 1 - {D}_{degradation} / {P}_{stray} * {t}_{LT} ) .$$

These estimations are of particularly great importance if the curing wavelength is equal to the operating wavelength. If necessary, first it is possible to increase the reflection to the desired value by way of increasing the number of layers and, second it is possible to increase the transmission at the curing wavelength by way of suitably detuning the outermost layer on the adhesive side composed of material having a higher refractive index by way of choosing a different layer thickness than for the other layers composed of material having a higher refractive index.

FIG. 11 illustrates one exemplary embodiment of a second optical module 1100. In the present example, the optical element 1101 is a convex lens that is transparent to an operating wavelength in the ultraviolet wavelength range. The lens 1101 is mounted into a holder 1103. For this purpose, the lens is fixedly adhesively bonded to the holder 1103 by a UV-curable adhesive 1105, specifically, in this example, outside the region used optically during operation. By way of example, epoxy-based adhesives that can be cured using UV radiation of the i-line of a mercury lamp are used as mounting adhesives. As a result of the irradiation of the lens during operation, in particular by stray light or multiple reflections, in the long term the adhesive may incur radiation damage and lose adhesion or become deformed, such that the lens 1101 is no longer held in the originally adjusted position in the holder 1103 and imaging aberrations may occur. Therefore, an adhesive protection coating 1111 comprising an absorbent layer 1110 and an anti-reflection coating 1112 is provided between lens 1101 and adhesive 1105. The anti-reflection coating 1112 can be applied by customary coating methods of thin-film technology such as thermal electron beam evaporation or magnetron sputtering, for example. In order to increase the mechanical strength of the optical module 1100, ion-assisted coating methods are preferably chosen in order to apply the adhesive protection coating 1111 and, in particular, the anti-reflection coating 1112 thereof.

In one embodiment, the anti-reflection coating of the adhesive protection coating is embodied as a coating with a refractive index gradient. A substantial anti-reflection effect is possible if the coating between the material of the optical element and the adhesive protection coating has a refractive index gradient which continuously changes from the refractive index of the material of the optical element through to the refractive index of the material of the adhesive protection coating.

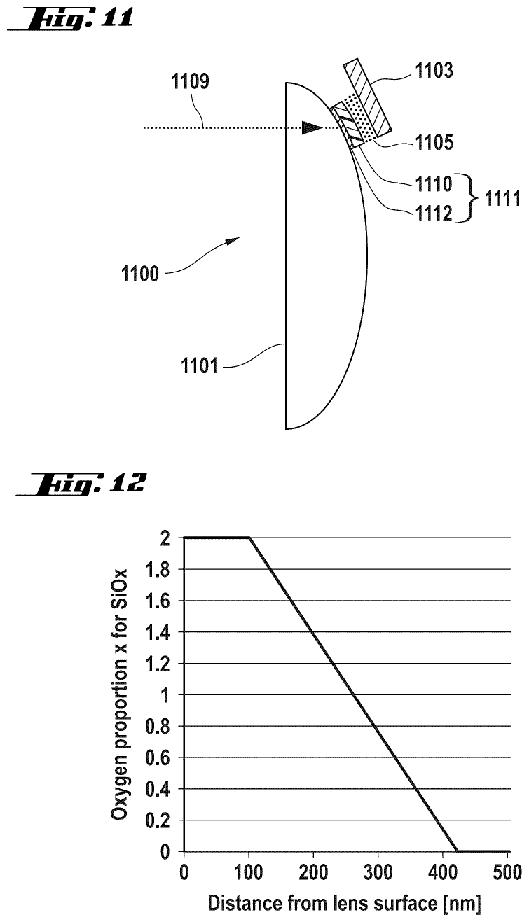

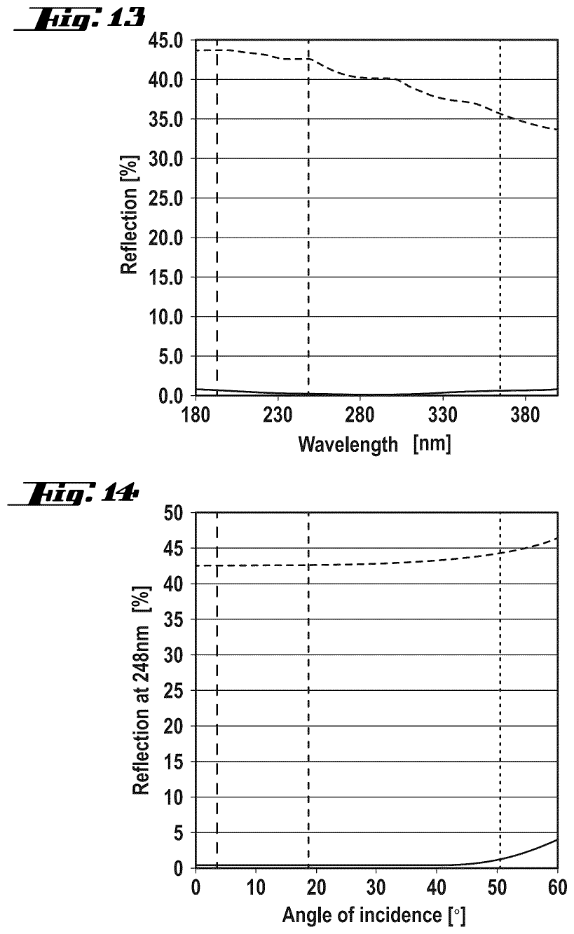

In the present example, consideration is given to an optical module in which the optical element is designed as a lens composed of quartz glass and a material of the absorbent layer of the adhesive protection coating is amorphous silicon, which strongly absorbs radiation at wavelengths of less than 400 nm. Between the lens and the amorphous silicon layer, for the anti-reflection effect an SiOₓ gradient layer is applied, the oxygen content of which decreases from the lens surface where x=2 continuously to x=0 at the transition to the silicon layer, as is illustrated in FIG. 12. For this purpose, for example, firstly silicon can be sputtered from a target reactively in a saturated oxygen atmosphere, with the result that firstly a SiO2 layer is formed. The oxygen content in the coating apparatus is then reduced continuously, with the result that the oxygen content in the SiOₓ layer also falls and x decreases from 2 to 0. Finally, silicon is sputtered in a high vacuum at a pressure of less than 10-5 mbar, i.e. without oxygen. FIG. 13 illustrates the reflection for the optical module thus obtained given quasi-normal incidence as a function of the wavelength. The vertical, varyingly dashed lines indicate the wavelengths 193 nm, 248 nm and 365 nm. The solid reflection profile shows the reflection of the optical module comprising an anti-reflective adhesive protection coating, i.e. comprising amorphous silicon for protecting the adhesive and the anti-reflection coating by way of the coating with a refractive index gradient according to FIG. 12. The dashed reflection profile shows for comparison the reflection of a corresponding optical module without an anti-reflection coating, i.e. only comprising amorphous silicon on quartz glass. Correspondingly, FIG. 14 illustrates the reflection at a wavelength of 248 nm as a function of the angle of incidence, the solid reflection profile showing the reflection with an anti-reflection coating and for comparison the dashed reflection profile showing the reflection without an anti-reflection coating on the adhesive protection coating composed of amorphous silicon. The anti-reflection coating of the adhesive protection coating via a coating with a refractive index gradient leads to a very low reflection of less than 1% over a very large wavelength range of 180 nm to 390 nm and over a very large angle-of-incidence range up to 50°, and so this kind of optical module can be used very flexibly.

In a further embodiment, the anti-reflection coating can have layers composed of a material having a higher refractive index at the operating wavelength and layers composed of a material having a lower refractive index in the operating wavelength range, wherein the layers composed of material having the higher refractive index and the layers composed of material having the lower refractive index are arranged alternately in each case. The resultant dielectric multilayered anti-reflection coating can be described analogously to the highly reflective coating of the first optical module as in FIGS. 3 and 4. The fundamental difference is that different layer thicknesses are employed. Whereas for an anti-reflection effect the optical thicknesses of a layer pair composed of materials having higher and lower refractive indices are substantially of the order of approximately one quarter of the operating wavelength of the respective optical clement, for a particularly high reflection they are of the order of approximately half the operating wavelength. For the optical thickness, the geometric thickness is weighted with the refractive index of the respective layer material. The specific thicknesses of the higher and lower refractive index layers are optimized for the highest possible anti-reflection effect. Suitable materials of the higher refractive index layers include, inter alia, aluminum oxide for wavelengths of 193 nm or more, hafnium oxide for wavelengths of 248 nm or more, and tantalum pentoxide for wavelengths of 365 nm or more. These materials, indicated by way of example, are scarcely absorbent above the wavelengths respectively indicated. Suitable material of the lower refractive index layers is silicon dioxide for, in particular, wavelengths of 193 nm or more. Applying both the higher and the lower refractive index layers using an ion-assisted coating process ensures a high mechanical stability and sufficiently good layer adhesion.

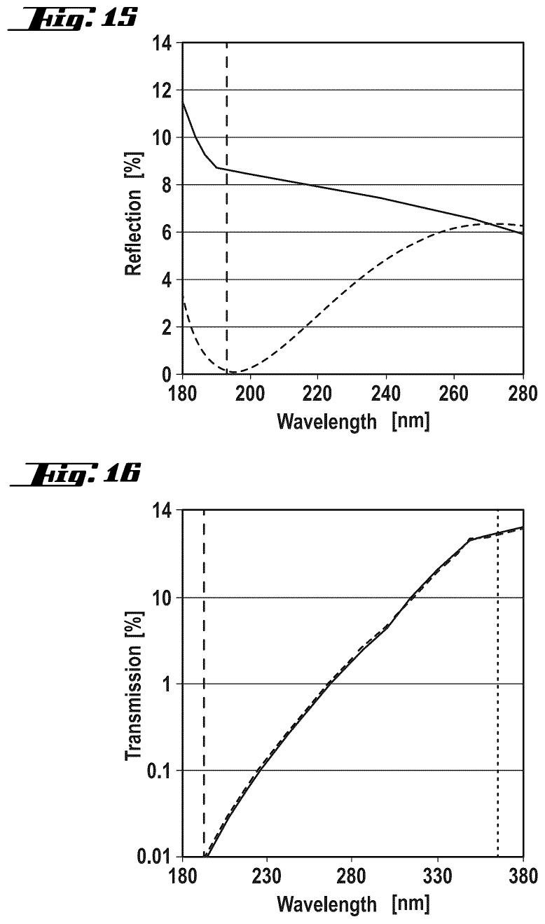

In FIG. 15 the reflection and in FIG. 16 the transmission as a function of the wavelength are illustrated for an optical module having a dielectric multilayered anti-reflection layer on its adhesive protection coating. In this case, the dashed vertical line denotes the operating wavelength of 193 nm and the dotted line denotes the wavelength of 365 nm, at which the adhesive is cured. The optical module has an optical element in the form of a lens composed of quartz glass and an adhesive protection coating in the form of a layer composed of tantalum pentoxide with a thickness of 180 nm. An anti-reflection coating applied thereto is in the form of a coating composed of 22 nm aluminum oxide, 33 nm silicon dioxide and 22 nm aluminum oxide. The dashed reflection and transmission profiles show the reflection and transmission with an anti-reflection coating, and the solid reflection and transmission profiles show for comparison the reflection and transmission without an anti-reflection coating. The anti-reflection coating by a multilayered dielectric coating results in an anti-reflection effect in a targeted manner around the operating wavelength, in the case of which, in conjunction with negligible transmission, the entire incident radiation is absorbed in the adhesive protection coating. In the case of the curing wavelength, by contrast, both with and without an anti-reflection coating, the transmission is very high in conjunction with low reflection and low absorption, such that the adhesive can be cured very well through the quartz glass lens and the adhesive protection coating composed of tantalum pentoxide.

Overall, as absorbent material for an adhesive protection coating, in a wavelength-dependent manner, it is possible to use any material which would also be suitable as a layer material having a higher refractive index for a multilayered anti-reflection coating or a multilayered highly reflective adhesive protection coating. For the absorption of UV radiation with a longer wavelength such as 365 nm, for instance, metals are suitable, more particularly chromium, which also has good adhesion properties on customary lens materials. What is suitable at shorter wavelengths such as in the range of 248 nm or 193 nm, for instance, is for example fluoride crystals such as calcium fluoride or else quartz glass, and what is suitable at longer wavelengths such as around 365 nm, for instance, is for example lead-containing glasses or borosilicate glasses. Depending on the choice of material for the adhesive protection coating and for the optical clement, an adhesion promoter can additionally be used as well.

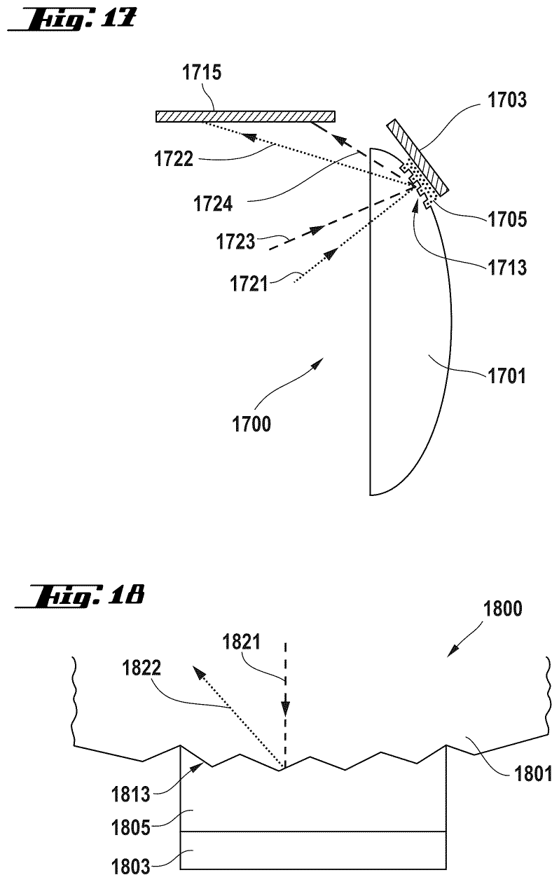

FIGS. 17 and 18 schematically illustrate a further optical module 1700, 1800, having an optical element 1701, 1801 for an operating wavelength in the ultraviolet wavelength range and a holder 1703, 1803, wherein the optical element 1701, 1801 is adhesively bonded to the holder 1703, 1803 by an adhesive 1705, 1805. The optical modules 1700, 1800 illustrated here have a diffractive structure 1713, 1813 in the region of the adhesive 1705, 1805. In the present example, the optical elements 1701, 1801 are embodied as lenses.

By virtue of the fact that the lenses 1701, 1801, in their edge region in which the respective holders 1703, 1803 are arranged, are structured in a targeted manner such that the radiation 1721, 1723, 1821 incident there is diffracted from the beam path, what can be achieved is that radiation 1721, 1723, 1821 does not reach the adhesive 1705, 1805 and damage it in the process, nor is radiation 1721, 1723, 1821 reflected at the lens edge with the contrast being reduced as a result, nor is radiation 1721, 1723, 1821 absorbed with a resulting contribution to lens heating that has a disturbing influence on the wavefront and thus the imaging. Diffractive structures can be chosen in the form of e.g. a periodic diffraction grating 1713 without inclination of the diffractive structures relative to the lens surface. The first and higher orders of diffraction are thereby deflected from the disturbing reflection path, wherein depending on diffraction efficiency it is necessary to ensure that the diffraction path leads into comparatively non-critical regions.

In the example illustrated in FIG. 17, a radiation absorber 1715 is provided on the optical module 1700. The radiation absorber has a low thermal coupling to the lens 1701 and substantially absorbs the radiation 1722, 1724 which is incident on it and which was diffracted from the beam path by the diffraction grating 1713, and so it finally removes said radiation from the optical module 1700.

It is highly advantageous however for the diffractive structure to be designed as an inclined structure 1813, in particular gratings such as blazed gratings or echelette gratings, for example, in which the zero order of diffraction is already diffracted from the beam path (see also FIG. 18). In the present example here the angle of inclination of the diffractive structure 1813 is designed such that the diffracted radiation 1822 is directed to a radiation absorber that brings about absorption as fully as possible, this radiation absorber not being illustrated in FIG. 18 for the sake of better clarity. In the present example, the depth of the structures 1813 is ¼ of the operating wavelength that is intended to be diffracted, that is to say 193 nm/4, i.e. approximately 48 nm, 248 nm/4, i.e. 62 nm or 365 nm/4, i.e. approximately 91 nm. If the structures 1813 are filled with adhesive 1805 as in the example illustrated in FIG. 18, the depth should also be divided by the refractive index of the adhesive. An etch stop layer can be used during the production of the diffractive structure, wherein the material of the etch stop layer should be as transparent as possible at the operating wavelength. By way of example, the diffractive structure can be produced by etching from a silicon dioxide layer having a thickness which corresponds to the structure depth to be etched and on an approximately 5 nm to 10 nm thick aluminum layer that is inert vis-à-vis a reactive etching process.

### LIST OF REFERENCE SIGNS

1 VUV lithography device
2 Wafer inspection system
3 Reflective optical element
4 Reflective optical element
5 Reflective optical element
6 Reflective optical element
10 Radiation source
11 Radiation
12 Illumination system
13 Mask
14 Projection system
15 Element to be exposed
20 Radiation source
21 Radiation
22 Optical system
23 Detector
25 Wafer
50 Optical element
51 Substrate
120 Lens
121 Mirror
140 Lens
141 Lens
220 Mirror
221 Mirror
300 Optical module
301 Optical element
303 Holder
305 Adhesive
307 Adhesive protection coating
309 UV radiation
401 Optical element
405 Adhesive
407 Adhesive protection coating
471, 471′ Higher refractive index layer
473 Lower refractive index layer
1100 Optical module
1101 Optical element
1103 Holder
1105 Adhesive
1109 UV radiation
1110 Absorbent layer
1111 Adhesive protection coating
1112 Anti-reflection coating
1210 Reflective surface
1700 Optical module
1701 Optical element
1703 Holder
1705 Adhesive
1713 Diffraction structure
1721 UV radiation
1722 UV radiation
1723 UV radiation
1724 UV radiation
1800 Optical module
1801 Optical element
1803 Holder
1805 Adhesive
1813 Diffraction structure
1821 UV radiation
1822 UV radiation

What is claimed is:

1. An optical module, comprising:
an optical element for an operating wavelength in an ultraviolet wavelength range;
a holder;
an adhesive adhesively bonding the optical element to the holder; and
an adhesive protection coating that is absorbent at the operating wavelength and is configured as an anti-reflection coating.

2. The optical module of claim 1, wherein the anti-reflection coating comprises layers composed of a material having a higher refractive index at the operating wavelength and layers composed of a material having a lower refractive index in a range of the operating wavelength, wherein the layers composed of material having the higher refractive index and the layers composed of material having the lower refractive index are alternately arranged.

3. The optical module of claim 1, wherein the anti-reflection coating comprises a coating with a refractive index gradient.

4. An optical module, comprising:
an optical element for an operating wavelength in the ultraviolet wavelength range;
a holder;
an adhesive adhesively bonding the optical element to the holder; and
a diffractive structure arranged in a region of the adhesive.

5. The optical module of claim 4, wherein the diffractive structure is arranged at an angle of inclination with respect to the normal to a surface of the optical element.

6. The optical module of claim 4, wherein it has a radiation absorber.

7. An optical module, comprising:
an optical element for an operating wavelength in an ultraviolet wavelength range;
a holder;
an adhesive adhesively bonding the optical element to the holder, wherein the adhesive is curable via irradiation at a curing wavelength in the ultraviolet wavelength range; and
an adhesive protection coating comprising a multilayered design and that is highly reflective and slightly absorbent in a range of the operating wavelength.

8. The optical module of claim 7, wherein the adhesive protection coating comprises three layers.

9. The optical module of claim 7, wherein the adhesive protection coating comprises layers composed of a material having a higher refractive index at the operating wavelength and layers composed of a material having a lower refractive index in the range of the operating wavelength, wherein the layers composed of the material having the higher refractive index and the layers composed of the material having the lower refractive index are alternately arranged.

10. The optical module of claim 7, wherein the adhesive protection coating comprises at least two layers of the material having the higher refractive index at the operating wavelength and at least one layer of the material having the lower refractive index in the operating wavelength.

11. The optical module of claim 7, wherein the adhesive protection coating comprises between three and sixteen layers of the material having the higher refractive index in the operating wavelength range and between three and sixteen layers of the material having the lower refractive index in the range of the operating wavelength.

12. The optical module of claim 7, wherein the adhesive protection coating comprises a layer composed of the material having the higher refractive index at the operating wavelength as an outermost layer on an adhesive side of the adhesive protection coating.

13. The optical module of claim 12, wherein the adhesive protection coating has a layer composed of the material having a higher refractive index at the operating wavelength as an outermost layer on its side facing away from the adhesive.

14. The optical module of claim 13, wherein a thickness of the outermost layer facing away from the adhesive or facing the adhesive is a different thickness than that of the other layers composed of the material having the higher refractive index at the operating wavelength.

15. The optical module of claim 9, wherein all the layers of a material have the same thickness.

16. The optical module of claim 7, wherein the operating wavelength is not equal to the curing wavelength, wherein the adhesive protection coating has a reflection of greater than 70%, at the operating wavelength and a transmission of greater than 90% at the curing wavelength.

17. The optical module of claim 16, wherein it is designed for an operating wavelength of around 193 nm or 248 nm and a curing wavelength of around 365 nm.

18. The optical module of claim 7, wherein the operating wavelength is equal to the curing wavelength, characterized in that the adhesive protection coating has a reflection of greater than 70% at the operating wavelength and a transmission of greater than 2% at the curing wavelength.

19. The optical module of claim 18, characterized in that it is designed for an operating wavelength and a curing wavelength of around 365 nm.

20. The optical module of claim 7, characterized in that the adhesive protection coating has at least one material from the group formed from silicon dioxide, aluminum oxide, hafnium dioxide, tantalum pentoxide, titanium dioxide, zinc sulfide, aluminum fluoride, cryolite, chiolite and magnesium fluoride.

21. The optical module of claim 20, characterized in that the adhesive protection coating has, as a material having a higher refractive index at the operating wavelength, one from the group formed from hafnium dioxide, aluminum oxide, tantalum pentoxide, titanium dioxide and zinc sulfide and has, as a material having a lower refractive index at the operating wavelength, one from the group formed from silicon dioxide, aluminum fluoride, magnesium fluoride, chiolite and cryolite.

22. The optical module of claim 1, wherein the optical element is designed as a lens.

23. An optical system comprising an optical module as claimed in claim 1.

24. A device comprising an optical module as claimed in claim 1, the device comprising a UV lithography device or an inspection device.
